(19) United States
(12) Patent Application Publication
(10) Pub. No.: US 2024/0055294 A1
(43) Pub. Date: Feb. 15, 2024

(54) METHODS AND APPARATUS FOR A SUSCEPTOR LIFT TOOL

(71) Applicant: ASM IP Holding B.V., Almere (NL)

(72) Inventors: Ruchik Bhatt, Chandler, AZ (US); Matthew Ricketts, Scottsdale, AZ (US)

(21) Appl. No.: 18/230,729

(22) Filed: Aug. 7, 2023

Related U.S. Application Data
(60) Provisional application No. 63/396,667, filed on Aug. 10, 2022.

(51) Int. Cl. H01L 21/687

(52) U.S. Cl. CPC H01L 21/68742

(57) ABSTRACT

Embodiments of the present invention provide a lift tool used to facilitate moving a susceptor. The lift tool includes a plate-shaped central region, a plurality of arms connected to and extending outward from the central region, wherein each arm includes a through-hole. The lift tool also includes a plurality of hooks extending through the through hole of a respective arm. Each hook may include a leg and a foot connected to the leg.

### CROSS-REFERENCE TO RELATED APPLICATIONS

This application is a nonprovisional of, and claims priority to and the benefit of, U.S. Provisional Patent Application No. 63/396,667, filed Aug. 10, 2022 and entitled “METHODS AND APPARATUS FOR A SUSCEPTOR LIFT TOOL,” which is hereby incorporated by reference herein.

### FIELD OF INVENTION

The present disclosure generally relates to methods and apparatus for a susceptor lift tool. More particularly, the present disclosure relates to an apparatus used to facilitate lifting and moving a susceptor from and/or to a reaction chamber.

### BACKGROUND OF THE TECHNOLOGY

Susceptors used in semiconductor manufacturing are disposed within a reaction chamber. The susceptor may need to be removed from the reaction chamber for maintenance from time to time. The removal/installation process can be challenging, due to risks of damaging the susceptor, and dangerous if not done correctly. Conventional tools used to remove the susceptor from the reaction chamber may be bulky and/or difficult to maneuver, causing higher risk for damaging the susceptor or other tool components.

### SUMMARY OF THE INVENTION

Various embodiments of the present technology may provide a lift tool used to facilitate moving a susceptor. The lift tool includes a plate-shaped central region, a plurality of arms connected to and extending outward from the central region, wherein each arm includes a through-hole. The lift tool also includes a plurality of hooks extending through the through hole of a respective arm. Each hook may include a leg and a foot connected to the leg.

According to one aspect, a lift tool comprises: a plate; a plurality of arms connected to and extending outward from the center plate, wherein each arm comprises a through-hole; and a plurality of hooks, each hook comprising: a leg extending through the through-hole of a respective arm, and comprising a first end and a second end; and a foot connected to the second end.

In one embodiment of the above lift tool, the plurality of arms comprises at least 6 arms.

In one embodiment of the above lift tool, each arm comprises a first end connected to the plate and a second end, and wherein the through-hole is adjacent to the second end.

In one embodiment of the above lift tool, the leg is linear and perpendicular to the arm.

In one embodiment of the above lift tool, the foot is perpendicular to the leg.

In one embodiment of the above lift tool, the leg and foot form an L-shape.

In one embodiment of the above lift tool, the hook is movably coupled to the arm.

In one embodiment of the above, the lift tool further comprises a first handle coupled to a first and second arm from the plurality of arms and a second handle coupled to a third and fourth arm from the plurality of arms.

According to another aspect, an assembly comprises: a lift tool, comprising: a plate; a plurality of arms connected to and extending outward from the center plate, wherein each arm comprises a through-hole; a plurality of hooks, each hook comprising: a leg extending through the through-hole of a respective arm, and comprising a first end and a second end; and a foot connected to the second end; and a stand, comprising: a base comprising a first surface and a second surface; a first plurality of supports, wherein each support comprises a first end connected to the first surface of the base and a second end extending away from the base; a ring comprising a first surface and a second surface, wherein the second surface is connected to the second end of the first plurality of supports; and a secondary support structure comprising a disk with a slot and a second plurality of supports connecting the disk to the first surface of the base.

In one embodiment of the above assembly, the leg and foot form an L-shape.

In one embodiment of the above assembly, the hook is movably coupled to the arm.

In one embodiment of the above assembly, the plurality of arms comprises at least 6 arms.

In one embodiment of the above assembly, the first plurality of supports has a first length, and the second plurality of supports has a second length that is less than the first length.

In one embodiment of the above assembly, each leg has a length in a range of 90 to 120, and each foot has a width in a range of 3 mm to 6.5 mm.

According to yet another embodiment, a lift tool comprises: a plate comprising a metal material; a plurality of arms extending radially outward from the center plate, wherein each arm comprises a through-hole; a plurality of hooks, each hook comprising: a leg extending through the through-hole of a respective arm, and comprising a first end comprising a threaded portion and a second end; and a foot connected to the second end.

In one embodiment of the above lift tool, each leg has a length in a range of 90 mm to 120 mm, and each foot has a width in a range of 3 mm to 6.5 mm.

In one embodiment of the above lift tool, the hook is rotatably coupled to the arm at the first end by a threaded fastener.

In one embodiment of the above lift tool, the leg and foot form an L-shape.

In one embodiment of the above, the lift tool further comprising a fastener coupled to a center of the plate.

In one embodiment of the above lift tool, the leg is linear and perpendicular to the arm.

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIG. 1 representatively illustrates a susceptor lift and stand in use in accordance with an embodiment of the present technology;

FIG. 2 representatively illustrates a susceptor lift and stand in use in accordance with an embodiment of the present technology;

FIG. 3 representatively illustrates a susceptor stand in accordance with an embodiment of the present technology;

FIG. 4A representatively illustrates a susceptor lift in accordance with an embodiment of the present technology;

FIG. 4B representatively illustrates an arm and related components of a susceptor lift in accordance with an embodiment of the present technology;

FIG. 5 illustrates a method of use of the susceptor lift in accordance with an embodiment of the present technology;

FIG. 6 representatively illustrates a top view of the susceptor lift in accordance with an embodiment of the present technology; and

FIG. 7 representatively illustrates a portion of the lift in accordance with an embodiment of the present technology.

It will be appreciated that elements in the figures are illustrated for simplicity and clarity and have not necessarily been drawn to scale. For example, the relative size of some of the elements in the figures may be exaggerated relative to other elements to help improve understanding of illustrated embodiments of the present disclosure.

### DETAILED DESCRIPTION OF EXEMPLARY EMBODIMENTS

Reference will now be made to the drawings wherein like reference numerals identify similar structural features or aspects of the subject disclosure.

The description of exemplary embodiments provided below is merely exemplary and is intended for purposes of illustration only; the following description is not intended to limit the scope of the disclosure or the claims. Moreover, recitation of multiple embodiments having stated features is not intended to exclude other embodiments having additional features or other embodiments incorporating different combinations of stated features.

The present disclosure generally relates to a susceptor lift and stand used during the maintenance of semiconductor devices.

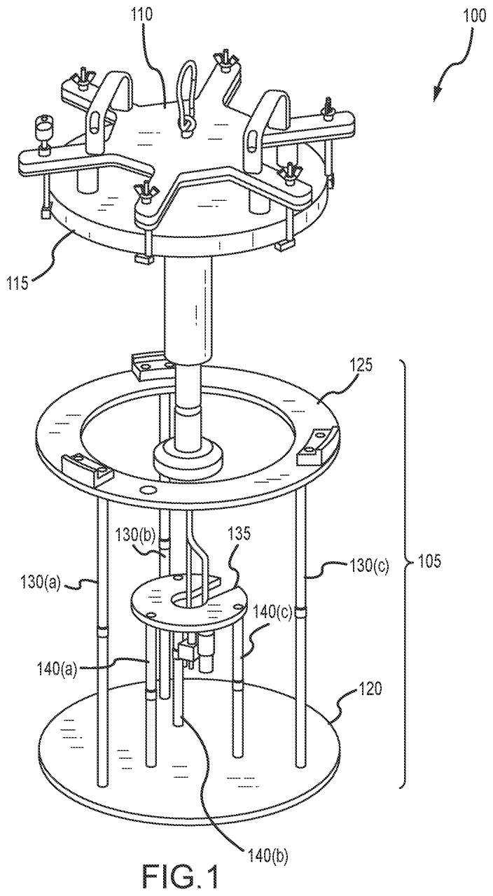

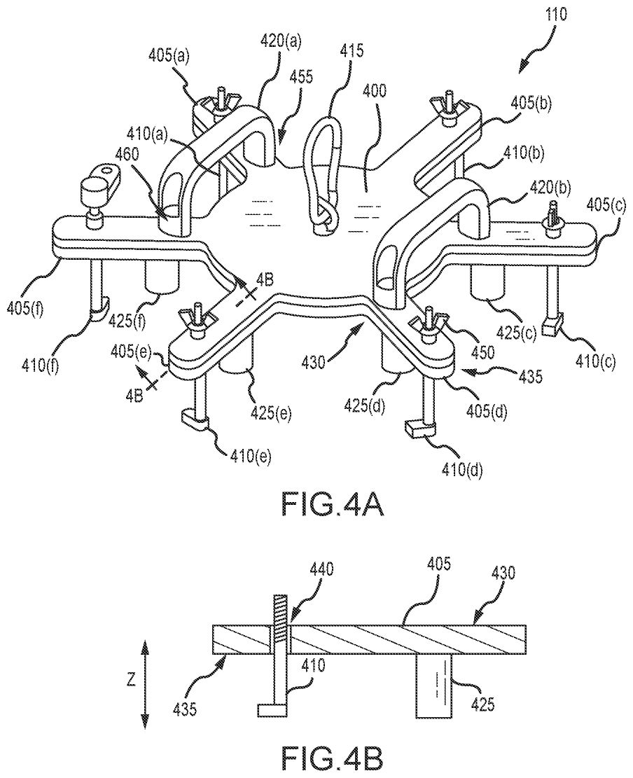

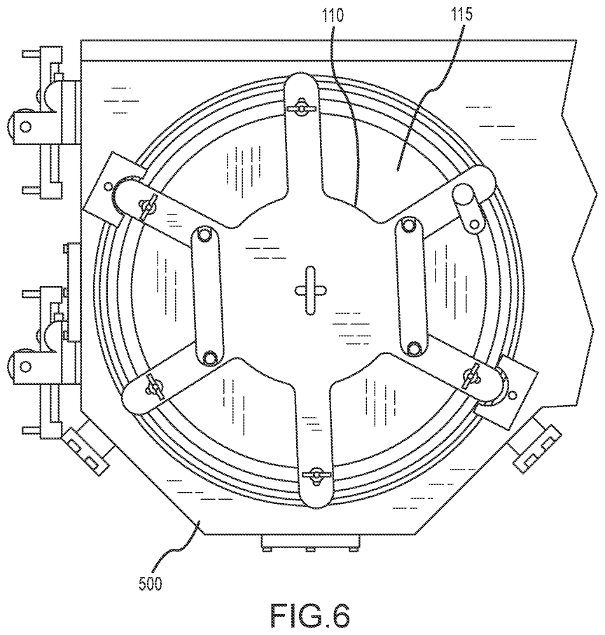

In various embodiments, and referring to FIGS. 1, 4A, 4B, 5 and 6, an apparatus 100 may comprise a lift tool 110 configured to attach to a susceptor 115 and facilitate moving the susceptor 115 out of or into a reaction chamber 500. The lift tool 110 may comprise a center plate 400 and a plurality of arms 405 extending radially outward from the center plate 400. The arms 405 may be spaced equally around the center plate 400, for example an angle between adjacent arms 405 may be the same for all arms. In an exemplary embodiment, the center plate 400 may have a flat, disk (i.e., plate) form. In an exemplary embodiment, the lift tool 110 may comprise 6 arms, such as a first arm 405(a), a second arm 405(b), a third arm 405(c), a fourth arm 405(d), a fifth arm 405(e), and a sixth arm 405(f), each arm comprising a first end 430 and a second end 435. Each arm 405 may comprise a through-hole 440 adjacent the second end 435. The arms may have a length from an edge of the center plate 400 to the second end 435 in a range of 2 inches to 10 inches. In an exemplary embodiment, the plurality of arms 405 may also have a flat form that is similar or the same as the center plate 400. In other words, the plurality of arms 405 may extend outward from the center plate 400 along a same plane as the center plate 400.

In some embodiments, the lift tool 110 may comprise a first plate and a second plate. The first plate may be fastened to the second plate with any suitable fastener, such as screws or the like. The first and second plates may have a same shape, in particular, each having the center plate 400 and plurality of arms 405. The first and second plates may be aligned such that the arms 405 of each overlap. The first plate may be formed from a continuous piece of metal material, such as aluminum, and the second plate may be formed from a continuous piece of plastic material, such as polytetrafluoroethylene. In other embodiments, the arms 405 may be coupled to the center plate 400 by any suitable method, such as by welding. In some embodiments, the lift tool 110 may be formed from a single material, such as a metal.

In various embodiments, the lift tool 110 may further comprise a plurality of hooks 410, such as a first hook 410(a), a second hook 410(b), a third hook 410(c), a fourth hook 410(d), a fifth hook 410(e), and a sixth hook 410(f). Each hook 410 may be disposed within the through-hole 440 of a respective arm 405 and adapted to rotate within the through-hole 440. For example, each arm 405 is associated with one hook 410.

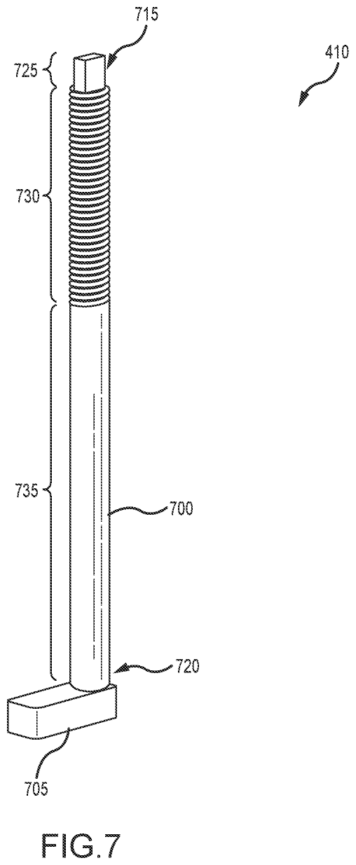

In an exemplary embodiment, and referring to FIG. 7, each hook 410 comprises a leg 700 and foot 705. The foot 705 may be fixedly attached to the leg 700, for example, the foot 705 may be welded to the leg 700. The leg 700 may comprise a first section 725 (i.e., a top section) at a first end 715 of the leg 700, a second section 730 comprising a threaded region, and a third section 735 at a second end 720 of the leg 700. The second section 710 may be disposed between the first section 725 and the third section 735. The foot 705 may be connected to the third section 715 at the second end 720. In an exemplary embodiment, the first section 725 may have a length in a range of 3 mm to 10 mm, the second section 730 may have a length in a range of 28 mm to 40 mm, and the third section 735 may have a length in a range of 55 mm to 65 mm. The leg 700 may have a total length in a range of 90 mm to 120 mm, for example 100 mm. The leg 700 may be formed from a metal material, such as a steel alloy or any other suitable metal. The second and third sections 730, 735 may have a cylindrical shape having a diameter in a range of 3 mm to 8 mm.

In various embodiments, the foot 705 may have dimensions that allow it to enter a gap between an edge of the susceptor 115 and a wall of the reaction chamber 500. For example, in one embodiment, the foot 705 has approximate dimensions of 6.5 mm (width)×5 mm (height)×18 mm (length). In other embodiments, the dimensions of the width may be less than 6.5 mm, for example in a range of 3 mm to 6.5 mm. In various embodiments, the foot 705 may be formed from a metal material, such as a steel alloy or any other suitable metal, and may be the same metal material as that of the leg 700.

Each hook 410 may be coupled to the arm 405 with a threaded fastener 450, such as a bolt and wing nut. For example, the second section 730 of the leg 700 may be threaded to mate with the threaded fastener to prevent the leg 700 from moving along a z-axis within the through-hole 440.

In various embodiments, the lift tool 110 may further comprise a center fastener 415, such as a hook, loop, or carabiner attached at a center of the plate 400. For example, an eye bolt may be screwed into the plate 400 and the center fastener 415 may couple to the eye bolt. The lift tool may further comprise a removable attachment, such as a snap link (not shown), coupled to the center fastener 415. The center fastener 415 may be formed from a metal material, such as a steel alloy, and have a strength suitable for supporting the weight of the susceptor 115, which weights approximately 20-50 lbs.

In various embodiments, the lift tool 110 may further comprise a plurality of handles 420, such as a first handle 420(a) and a second handle 420(b), suitable for grasping with human hands. In an exemplary embodiment, the handles 420 may be formed from a metal material, such as aluminum. In an exemplary embodiment, the lift tool 110 may comprise two handles arranged on opposite sides of the lift tool 110 and in parallel with each other. Each handle 420 may be substantially U-shaped and comprise a first end 455 and a second end 460. The first end 455 may be attached to a top surface of one arm from the plurality of arms and the second end may be attached to a top surface of a different arm from the plurality of arms. For example, the first end 455 may be attached to the first arm 405(a) and the second end 460 may be attached to the sixth arm 420(f).

In various embodiments, the lift tool 110 may further comprise a plurality of spacers 425 configured to directly contact the susceptor 115, when in use. In various embodiments, the plurality of spacers 425 are connected to the bottom surface of the lift tool 110 and extend away from the bottom surface. In an exemplary embodiment, each spacer 425 is positioned along a respective arm. In one embodiment, the spacers 425 are cylindrical shaped and formed from a plastic material, such as polytetrafluoroethylene

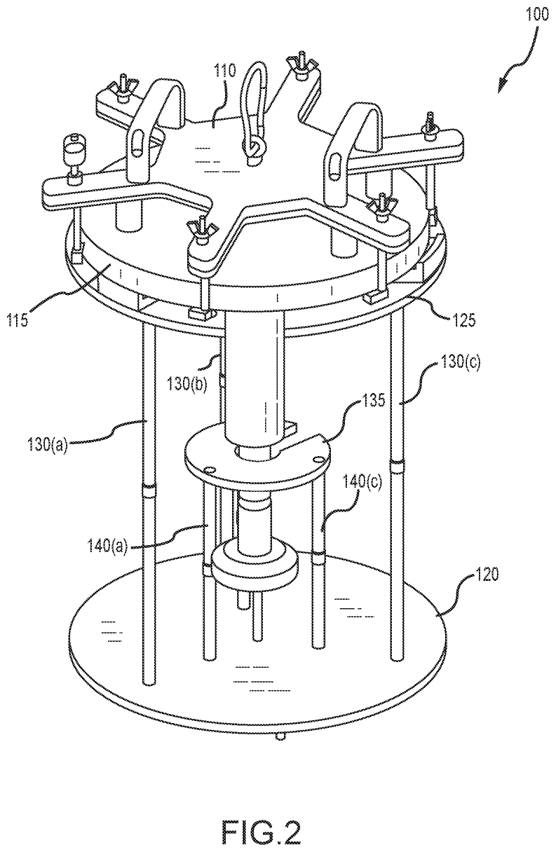

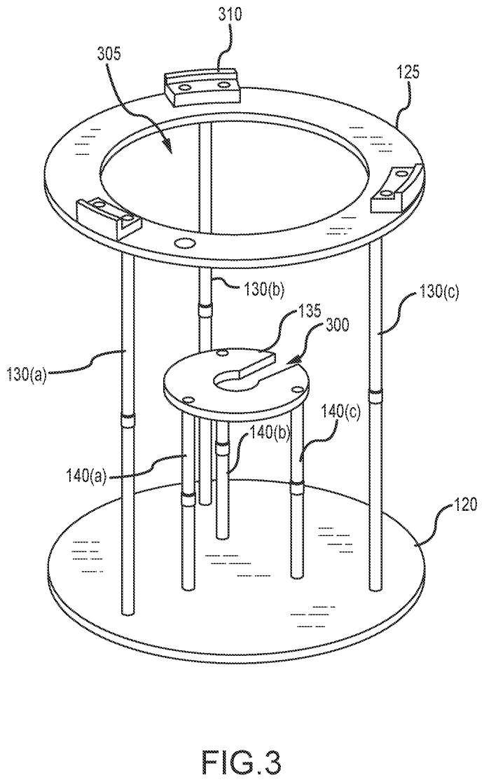

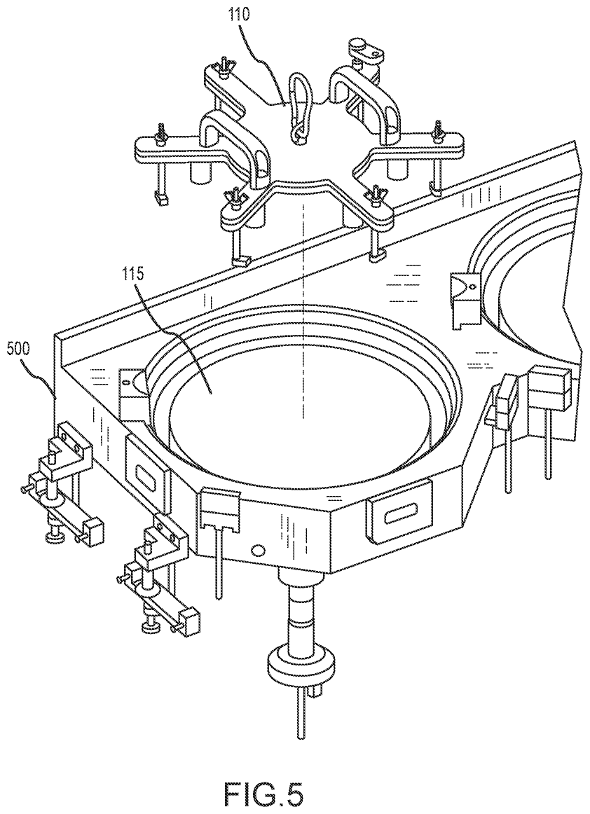

In various embodiments, and referring to FIGS. 1-3, the apparatus 100 may further comprise a stand 105 configured to support the susceptor 115 after the susceptor 115 is removed from the reaction chamber 500 (FIG. 5). In various embodiments, the stand 105 may comprise a base 120 and a support ring 125.

In various embodiments, the stand 105 may further comprise a first plurality of supports 130, such as a first support 130(a), a second support 130(b), and a third support 130(c). In an exemplary embodiment, the plurality of supports 130 comprises at least three supports 130. The supports 130 may connect the base 120 to a bottom surface of the support ring 125. In particular, the supports 130 may be perpendicular to the base 120 and the support ring 125, and separate the support ring 125 from the base 120 by a fixed distance. In various embodiments, the supports 130 may be formed from a metal material, such as a steel alloy or any other suitable metal. The supports 130 may be affixed to the base 120 and support ring 125 with a threaded fastener, such as a screw.

In an exemplary embodiment, the support ring 125 may have a circular shape with an opening in the middle. An outer circumference of the support ring 125 may be the same as a circumference of the base 120. In various embodiments, the support ring 125 may be formed from a metal material, such as aluminum or any other suitable metal or metal alloy.

In various embodiments, the support ring 125 may further comprise a plurality of aligners 310 affixed to a top surface of the support ring 125.

The stand 105 may further comprise a secondary support structure comprising a disk 135 with a slot 300 or cutout (e.g., a keyhole slot). The disk 135 may be support by and connected to the base 120 with a second plurality of supports 140, such as a first support 140(a), a second support 140(b), and a third support 140(c). In various embodiments, the secondary support structure may comprise at least three supports 140. The supports 140 may be affixed to the base 120 and the disk 135 with a threaded fastener, such as a screw or the like. In various embodiments, the slot 300 may be shaped to accommodate a shaft of the susceptor 115. The disk 135 may be formed from a plastic material, such as polytetrafluoroethylene, and the second plurality of supports 140 may be formed from a metal material such as steel, steel alloy, or any other suitable metal.

In various embodiments, the lift tool 110 may be used to remove the susceptor 115 from the reaction chamber 500 and/or to place the susceptor 115 into the reaction chamber 500. The stand 105 may be used to hold or otherwise support the susceptor 115 after it has been removed from the reaction chamber 500.

In one method in which the susceptor is inside the reaction chamber, the lift tool 110 may be used to remove the susceptor 115 from the reaction chamber 500. Initially, each foot 705 is rotated such that the direction of each foot 705 is substantially perpendicular to the respective arm 405. In this position, each foot 705 can pass through a gap between the edge of the susceptor 115 and an interior wall of the reaction chamber 500.

The lift tool 110 may be placed on the top surface of the susceptor 115, with the spacers 425 directly contacting the top surface of the susceptor 115. Once all of the spacers 425 are in contact with the susceptor 115, each hook 410 is rotated such that each foot 705 faces inwards toward the center plate 400 and is parallel with the respective arm 405. Once rotated inward, each foot 705 is positioned below a bottom surface of the susceptor 115. After all of the feet 705 have been rotated inward, the threaded fastener 450 is turned to lift the foot 705 and bring the foot 705 in contact with the bottom surface of the susceptor 115. In other words, when the threaded fastener 450 is turned, the leg 700 and foot 705 move upwards so that the foot 705 is in direct contact with the bottom surface of the susceptor 115 and the foot 705 puts direct pressure on the susceptor 115. All other remaining threaded fasteners 450 are tightened in the same manner.

Once all of the threaded fasteners 450 have been tightened, the susceptor 115 may be lifted out of the reaction chamber 500 via the handles 420(a), 420(b) and/or the center fastener 415. Once removed from the reaction chamber 500, the susceptor 115 may be placed on the stand 105 for temporary storage and/or maintenance.

The process described above can be performed in reverse order to place the susceptor 115 back into the reaction chamber 500.

In the foregoing description, the technology has been described with reference to specific exemplary embodiments. The particular implementations shown and described are illustrative of the technology and its best mode and are not intended to otherwise limit the scope of the present technology in any way. Indeed, for the sake of brevity, conventional manufacturing, connection, preparation, and other functional aspects of the method and system may not be described in detail. Furthermore, the connecting lines shown in the various figures are intended to represent exemplary functional relationships and/or steps between the various elements. Many alternative or additional functional relationships or physical connections may be present in a practical system.

The technology has been described with reference to specific exemplary embodiments. Various modifications and changes, however, may be made without departing from the scope of the present technology. The description and figures are to be regarded in an illustrative manner, rather than a restrictive one and all such modifications are intended to be included within the scope of the present technology. Accordingly, the scope of the technology should be determined by the generic embodiments described and their legal equivalents rather than by merely the specific examples described above. For example, the steps recited in any method or process embodiment may be executed in any order, unless otherwise expressly specified, and are not limited to the explicit order presented in the specific examples. Additionally, the components and/or elements recited in any apparatus embodiment may be assembled or otherwise operationally configured in a variety of permutations to produce substantially the same result as the present technology and are accordingly not limited to the specific configuration recited in the specific examples.

Benefits, other advantages and solutions to problems have been described above with regard to particular embodiments. Any benefit, advantage, solution to problems or any element that may cause any particular benefit, advantage or solution to occur or to become more pronounced, however, is not to be construed as a critical, required or essential feature or component.

The terms “comprises”, “comprising”, or any variation thereof, are intended to reference a non-exclusive inclusion, such that a process, method, article, composition or apparatus that comprises a list of elements does not include only those elements recited, but may also include other elements not expressly listed or inherent to such process, method, article, composition or apparatus. Other combinations and/or modifications of the above-described structures, arrangements, applications, proportions, elements, materials or components used in the practice of the present technology, in addition to those not specifically recited, may be varied or otherwise particularly adapted to specific environments, manufacturing specifications, design parameters or other operating requirements without departing from the general principles of the same.

The present technology has been described above with reference to an exemplary embodiment. However, changes and modifications may be made to the exemplary embodiment without departing from the scope of the present technology. These and other changes or modifications are intended to be included within the scope of the present technology, as expressed in the following claims.

1. A lift tool, comprising:
a plate;
a plurality of arms connected to and extending outward from the center plate, wherein each arm comprises a through-hole; and
a plurality of hooks, each hook comprising:
a leg extending through the through-hole of a respective arm, and comprising a first end and a second end; and
a foot connected to the second end.

2. The lift tool according to claim 1, wherein the plurality of arms comprises at least 6 arms.

3. The lift tool according to claim 1, wherein each arm comprises a first end connected to the plate and a second end, and wherein the through-hole is adjacent to the second end.

4. The lift tool according to claim 1, wherein the leg is linear and perpendicular to the arm.

5. The lift tool according to claim 1, wherein the foot is perpendicular to the leg.

6. The lift tool according to claim 1, wherein the leg and foot form an L-shape.

7. The lift tool according to claim 1, wherein the hook is movably coupled to the arm.

8. The lift tool according to claim 1, further comprising a first handle coupled to a first and second arm from the plurality of arms and a second handle coupled to a third and fourth arm from the plurality of arms.

9. An assembly, comprising:
a lift tool, comprising:
a plate;
a plurality of arms connected to and extending outward from the center plate, wherein each arm comprises a through-hole;
a plurality of hooks, each hook comprising:
a leg extending through the through-hole of a respective arm, and comprising a first end and a second end; and
a foot connected to the second end; and
a stand, comprising:
a base comprising a first surface and a second surface;
a first plurality of supports, wherein each support comprises a first end connected to the first surface of the base and a second end extending away from the base;
a support ring comprising a first surface and a second surface, wherein the second surface is connected to the second end of the first plurality of supports; and
a secondary support structure comprising a disk with a slot and a second plurality of supports connecting the disk to the first surface of the base.

10. The assembly according to claim 9, wherein the leg and foot form an L-shape.

11. The assembly according to claim 9, wherein the hook is movably coupled to the arm.

12. The assembly according to claim 9, wherein the plurality of arms comprises at least 6 arms.

13. The assembly according to claim 9, wherein the first plurality of supports has a first length, and the second plurality of supports has a second length that is less than the first length.

14. The assembly according to claim 9, wherein each leg has a length in a range of 90 to 120, and each foot has a width in a range of 3 mm to 6.5 mm.

15. A lift tool, comprising:
a plate comprising a metal material;
a plurality of arms extending radially outward from the center plate, wherein each arm comprises a through-hole;
a plurality of hooks, each hook comprising:
a leg extending through the through-hole of a respective arm, and comprising a first end comprising a threaded portion and a second end; and
a foot connected to the second end.

16. The lift tool according to claim 15, wherein each leg has a length in a range of 90 mm to 120 mm, and each foot has a width in a range of 3 mm to 6.5 mm.

17. The lift tool according to claim 15, wherein the hook is rotatably coupled to the arm at the first end by a threaded fastener.

18. The lift tool according to claim 15, wherein the leg and foot form an L-shape.

19. The lift tool according to claim 15, further comprising a fastener coupled to a center of the plate.

20. The lift tool according to claim 15, wherein the leg is linear and perpendicular to the arm.
